(19) United States
(12) Patent Application Publication
(10) Pub. No.: US 2009/0078300 A1
(43) Pub. Date: Mar. 26, 2009

(54) DISTRIBUTED MAXIMUM POWER POINT TRACKING CONVERTER

(75) Inventors: Simon S. Ang, Fayetteville, AR (US); Keith C. Burgers, Fayetteville, AR (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(73) Assignee: EFFICIENT SOLAR POWER SYSTEM, INC.

(21) Appl. No.: 12/207,365

(22) Filed: Sep. 9, 2008

Related U.S. Application Data
(60) Provisional application No. 60/971,421, filed on Sep. 11, 2007.

(51) Int. Cl. H01L 31/042

(52) U.S. Cl. 136/244

(57) ABSTRACT

The present system and method provides a maximum power point tracking converter for use with a solar cell group in a distributed manner within a solar panel. According to one embodiment, one or more solar cells within a solar panel are grouped and coupled to a distributed converter that extracts maximum power from the coupled solar cell group.

The present application claims the benefit of and priority to U.S.Provisional Patent Application No. 60/971,421 filed on Sep. 11, 2007, entitled “A Distributed Maximum Power Point Tracker and Converter.” U.S. Provisional Patent Application 60/971,421 is herein incorporated by reference.

### FIELD

The present method and system relates to a solar photovoltaic generation system and more particularly relates to the control and management of electrical energy generated by solar photovoltaic generation system.

### BACKGROUND

Solar arrays or panels generate electric power by converting solar energy into electrical energy. The power output of a solar array varies, among other factors, with the light intensity, the degree of insolation, the array voltage, and the array temperature.

A solar array consists of a collection of photovoltaic solar cells, and the array voltage of the solar array is determined by the number of photovoltaic solar cells connected in series and the cell voltage of each photovoltaic solar cell. FIG. 1 illustrates a voltage-current characteristics plot of a typical photovoltaic solar cell. Under no external load, the terminals of the solar cell measures an open-circuit voltage but no current flows therebetween. The open-circuit voltage of the solar array increases as the intensity of incident light illuminating the surface of the solar array increases. For a given amount of light intensity, as the load starts to draw power from the solar array, the output voltage of the solar array decreases while the output current increases. As more power is drawn, the operating point reaches the maximum power point (MPP), where the output power drawn from the solar array is maximized. If the load further draws the current from the solar array beyond the maximum power point, the output voltage further decreases, so does the output power drawn from the solar array. As the load further increases, the operating point eventually reaches the short-circuit current point with zero voltage output, which produces no power.

Solar systems equipped with maximum power point tracking (MPPT) capability track the output current-voltage and regulate the impedance at the terminals to extract maximum output power from the solar array. MPPT is particularly effective during cold weather, on cloudy or hazy days, or when the battery is deeply discharged. MPPT allows for driving a load at its maximum power by dynamically adjusting the impedance of the load to the operating condition of the solar array. For example, when an MPPT-capable solar system drives an electric motor directly from the solar array, the solar system can adjust the current draw of the solar array by varying the motor's speed so that the motor runs at its maximum power.

Solar cells producing lower cell voltage are serially connected in a string to produce a higher output voltage. The output voltage of a solar cell string consisting of multiple solar cells is the sum of the cell voltages of the individual solar cells, but the output current of the solar cell string is limited by the current of the least productive solar cell in the string.

Shading or partial illumination changes the output current-voltage characteristics of a solar array. The impedance of a shaded solar cell increases to the point where it generates little or no power. When a solar panel contains multiple solar cell strings connected in series including a shaded area, the high impedance of the shaded solar cells causes power dissipation instead of power generation, thus decreasing the output power of the entire solar panel even though the remaining solar cells continue to generate power. In such a case, a bypass diode is connected to the shaded solar cell in parallel so that the power dissipation caused by the shaded solar cell is minimized. The bypass diode reduces the voltage loss caused by the shaded solar cell, thus the local heating due to the power dissipation by the shaded solar cell is diminished. The current flowing through and the forward bias voltage of the bypass diode may still contribute to the power loss of the solar cell string, but the power loss by the bypass diode is significantly lower than the power loss caused by the shaded solar cell.

In order to efficiently bypass shaded solar cells and to minimize power loss caused by shading, bypass diodes are placed in parallel with each solar cell in the solar array. However, the parallel configuration of a bypass diode with each solar cell not only increases the total cost of the system, but also decreases the output power of each solar cell due to the forward bias voltage of the bypass diode. Therefore, the benefits of adding bypass diodes need to be well balanced with the power loss introduced by the bypass diodes.

Conventional MPPT systems run MPPT software algorithms using a microcontroller, a microprocessor, or a digital signal processor such that power draw from the attached solar array is continuously monitored and adjusted. One of drawbacks of such centrally controlled MPPT systems is that they may not well adapt to locally varying operating conditions, particularly when the system has a number of solar cells covering a wide area. For example, such MPPT systems may enter into a low-power mode even when the solar array is partially shaded. In such a case, substantially lower power is drawn from the solar array than the maximum power that the array is capable of generating.

From the foregoing, there is a need for a simple and efficient maximum power point tracking solar converter under varying operating conditions that uses cost-effective analog and digital, or mixed-signal circuit components in conjunction with a small number of solar cells in a group.

### SUMMARY

The present system and method provides a maximum power point tracking converter for use with a solar cell group in a distributed manner within a solar panel. According to one embodiment, one or more solar cells within a solar panel are grouped and coupled to a distributed converter that extracts maximum power from the coupled solar cell group.

The above and other preferred features described herein, including various novel details of implementation and combination of elements, will now be more particularly described with reference to the accompanying drawings and pointed out in the claims. It will be understood that the particular methods and circuits embodying the invention are shown by way of illustration only and not as limitations of the invention. As will be understood by those skilled in the art, the principles and features of the teachings herein may be employed in various and numerous embodiments without departing from the scope of the claims.

### BRIEF DESCRIPTION OF THE DRAWINGS

The accompanying drawings, which are included as part of the present specification, illustrate the presently preferred embodiment of the present invention and together with the general description given above and the detailed description of the preferred embodiment given below serve to explain and teach the principles of the present invention.

FIG. 1 illustrates a voltage-current characteristics plot of a typical photovoltaic solar cell;

FIG. 2A illustrates an exemplary MPPT system, according to one embodiment;

FIG. 2B illustrates a functional diagram of an exemplary MPPT system, according to one embodiment;

FIG. 3 illustrates an exemplary converter and its associated current-sensing block, according to one embodiment;

FIG. 4 illustrates an exemplary MPPT controller, according to one embodiment;

FIG. 5 illustrates an exemplary duty cycle adjust block, according to one embodiment;

FIG. 6 illustrates an exemplary voltage control block, according to one embodiment;

FIG. 7 illustrates an exemplary buck converter, according to one embodiment;

FIG. 8 illustrates an exemplary solar array with distributed converters, according to one embodiment; and

FIG. 9 illustrates an exemplary solar panel connected to a power utility grid, according to one embodiment.

It should be noted that the figures are not necessarily drawn to scale and that elements of similar structures or functions are generally represented by like reference numerals for illustrative purposes throughout the figures. It also should be noted that the figures are only intended to facilitate the description of the various embodiments described herein. The figures do not describe every aspect of the teachings disclosed herein and do not limit the scope of the claims.

### DETAILED DESCRIPTION

The present system and method provides maximum power point tracking (MPPT) for use with a solar cell group in a solar array. According to one embodiment, the distributed maximum power point tracking converter comprises a power sensing block for measuring a power signal associated with the power drawn from each solar cell group and a duty cycle adjust block for measuring and adjusting duty cycle for each solar cell group. A power comparator compares the power signal with previously measured power signal and generates a first logical signal. A duty cycle comparator compares the duty cycle with previously measured duty cycle and generates a second logical signal. A logic comparator provides a control signal for the duty cycle adjust block using the first logical signal from the power comparator and the second logical signal from the duty cycle comparator. The distributed maximum power point tracking converter, in integrated or discrete form, may be embedded within or outside of the solar panels and coupled to a central electrical bus to charge storage batteries or to deliver electrical energy to electrical loads such as an inverter tied to a power utility grid.

According to one embodiment, a maximum-power peak detection control is added to a switching converter that extract the maximum power from a single or a plurality of solar cells based on comparison of the present value of the current or voltage to the previous value of the current or voltage. If the present value of the current or voltage is larger than the previous value of the current of voltage, the duty cycle of the switching converter is adjusted such that it will provide a maximum power to any output load. The previous value of the current or voltage is stored or held in a resistor-capacitor storage circuit. According to one embodiment, the maximum power point tracking is implemented using analog and digital, or mixed-signal circuits without a need for a microcontroller, a microprocessor, or a digital signal processor.

In the following description, for purposes of explanation, specific nomenclature is set forth to provide a thorough understanding of the present invention. However, it will be apparent to one skilled in the art that these specific details are not required in order to practice the present invention.

Each of the additional features and teachings disclosed below may be utilized separately or in conjunction with other features and teachings to provide distributed MPPT systems and methods for designing and using the same. Representative examples of the present invention, which examples utilize many of these additional features and teachings both separately and in combination, will now be described in further detail with reference to the attached drawings. This detailed description is merely intended to teach a person of skill in the art further details for practicing preferred aspects of the present teachings and is not intended to limit the scope of the invention. Therefore, combinations of features and steps disclosed in the following detail description may not be necessary to practice the invention in the broadest sense, and are instead taught merely to particularly describe representative examples of the present teachings.

Moreover, the various features of the representative examples and the dependent claims may be combined in ways that are not specifically and explicitly enumerated in order to provide additional useful embodiments of the present teachings. In addition, it is expressly noted that all features disclosed in the description and/or the claims are intended to be disclosed separately and independently from each other for the purpose of original disclosure, as well as for the purpose of restricting the claimed subject matter independent of the compositions of the features in the embodiments and/or the claims. It is also expressly noted that all value ranges or indications of groups of entities disclose every possible intermediate value or intermediate entity for the purpose of original disclosure, as well as for the purpose of restricting the claimed subject matter.

It is expressly noted that the component values shown in the drawings are merely representative and may be changed as required to optimize the performance. It is expressly noted that the schematics themselves may be subject to variation as required by operational requirements.

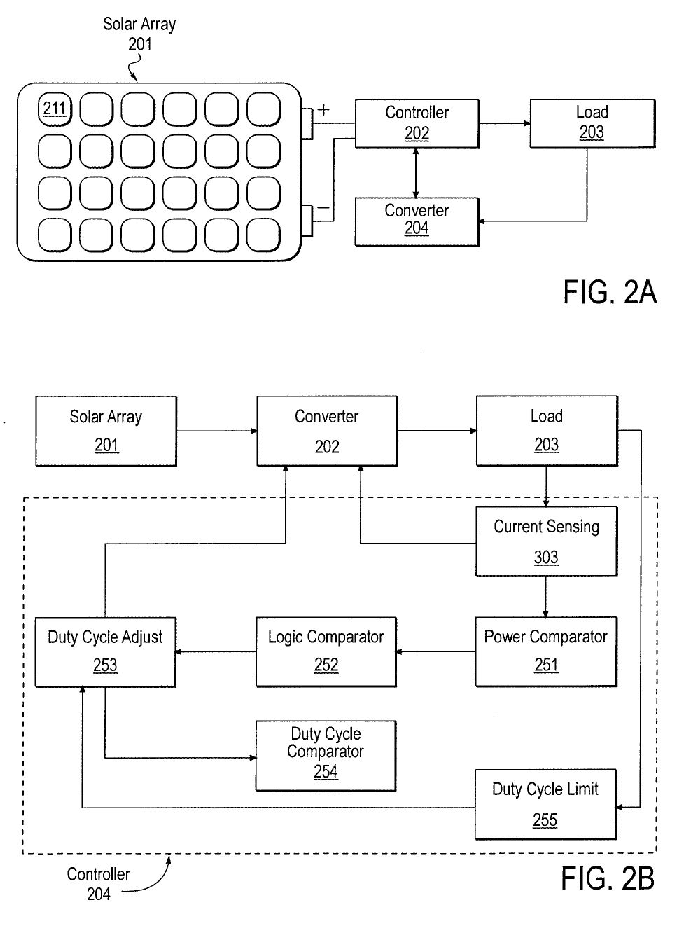

FIG. 2A illustrates an exemplary MPPT system, according to one embodiment. Solar array 201 contains a string of solar cells 211 from which converter 202 draws electrical power and supplies the electrical power to load 203. Solar array 201 may be composed of several solar panels, and each solar panel may include a number of solar cells 211 therein. It is appreciated that the configuration of solar array, or panels may vary without deviating the scope of the present invention. It is also appreciated that solar cell 211 may be of various types of solar cells including amorphous solar cells, crystalline solar cells, or thin film solar cells of any sizes and forms but is not limited thereto. The number of solar cells 211 grouped in a string is determined based on system configuration (e.g., specification of converter 202 and controller 204, open-circuit voltage of individual solar cell 211) as well as the efficiency of the distributed converter 202 and controller 204 in light of the added cost. According to one embodiment, converter 202 may be a boost converter, or a buck converter, a buck-boost converter, or push-pull converter, all of which are well known in the art. Load 203 may represent a battery that stores the electrical energy generated by solar array 201 or an electrical load such as a motor, a light, an off-grid inverter, or a grid-tied inverter. Controller 204 senses the voltage and/or current associated with load 203 and regulates controller 204 and converter 202 to extract maximum power from solar array 201.

According to one embodiment, controller 204 contains enhancements over the prior arts. For example, maximum power peak is detected for a single solar cell or each group of solar cells using analog/digital circuitries without a microcontroller, a microprocessor, or a digital signal processor, thus the MPPT capability is distributed to provide an improved efficiency.

FIG. 2B illustrates a functional diagram of an exemplary MPPT system, according to one embodiment. Current sensing circuit 303 of controller 204 senses the current drawn from load 203 and generates a voltage signal proportional to the draw current. The voltage signal is amplified and filtered and then sent to power comparator 251, which along with duty cycle adjust block 253 ensures that maximum power is extracted by load 203.

According to one embodiment, logic comparator 252 receives signals from power comparator 251 as well as duty cycle comparator 254 and generates an output to duty cycle adjust block 253, which adjusts the duty cycle of converter 202. Controller 204 contains duty cycle limit block 255, which is an over-voltage protection circuit that limits the upper bound of duty cycle using duty cycle limit block 255. Controller 204 may be integrated into converter 202 or implemented as a separate controller coupled to converter 202.

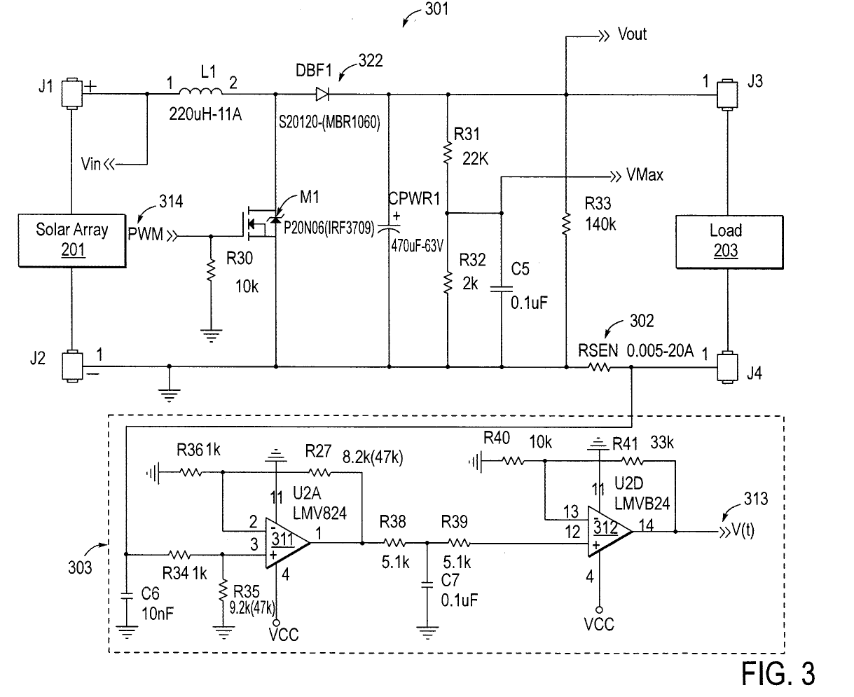

FIG. 3 illustrates an exemplary converter containing a current-sensing block, according to one embodiment. Converter 301 boosts the voltage output from a solar array 201. Converter 301 contains current sensing circuit 303 across resistor 302 comprising difference amplifier 311 and integrator 312. According to one embodiment, current sensing circuit 303 provides output voltage 313 that is also represented herein by V(t). Output voltage signal 313 is proportional to the output current of load 203 and is fed to a controller 204. In accordance with Ohm's law, the power utilized or dissipated by a load is equal to the square of the voltage across the load divided by the load resistance, and alternatively to the square of the current passing through the load multiplied by the load resistance. Since the output power is proportional to the square of the output current to which output voltage signal 313 is proportional, output voltage signal 313 is used as a reference signal to extract maximum power from solar array 201.

According to another embodiment, output voltage 313 is obtained by sensing the output voltage of load 203. Alternatively, the combination of output current and output voltage of 203 might be used to obtain a power signal that represents the power extracted from solar array 201. Power comparator 251 continuously samples output current and/or output voltage and provides the power signal to logic comparator 252. According to one embodiment, power comparator 251 generates the power signal by comparing the present power signal with the rolling average of past sampled power signals.

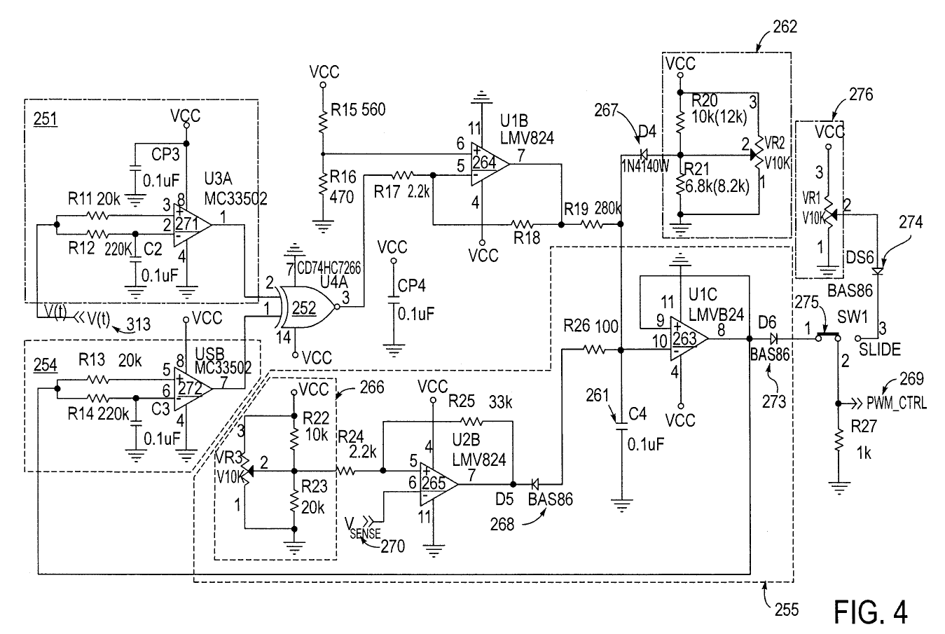

FIG. 4 illustrates an exemplary MPPT controller, according to one embodiments MPPT controller 204 is composed of several functional blocks: power comparator block 251, logic comparator block 252, duty cycle adjust block 253, duty cycle comparator block 254, and duty cycle limit and shutdown block 255. Power comparator 251 compares the present value of output voltage signal 313, which represents the current draw, thus power output of load 203, with the previous value. Duty cycle comparator 254 compares the present value of the duty cycle with the previous value. Logic comparator 252 receives the outputs from power comparator 251 and duty cycle comparator 254 and determines whether to increase or decrease the next duty cycle value.

According to one embodiment, power comparator 251 and duty cycle comparator 254 are analog comparators making use of resistor-capacitor network to retain previous signals at their inverting inputs. This configuration of analog resistor-capacitor network has greater cost and power advantages over software comparator algorithms implemented in a microcontroller, a microprocessor or a digital signal processor, and can be readily implemented in an integrated circuit form.

When controller 204 turns on, the voltage at duty cycle capacitor 261 is charged to an initial voltage level determined by the voltage divider 262. This initial value at duty cycle capacitor 261 is fed through a voltage follower 263 to serve as PWM CTRL signal 269, which is an input to duty cycle adjust block 253. Converter 202 draws power as determined by the duty cycle.

As the output power of converter 202 increases, current sensing circuit 303 senses the increase in load current delivered to load 203 and generate output voltage 313. Using difference amplifier 271, power comparator 251 compares the current value of output voltage 313, which is proportional to load current with the previously held output voltage 313 at its inverting input. The output of power comparator 251 is governed by output voltage 313 in comparison to its previous value; when the current value of output voltage 313 is greater than the previously held value, the output of power generator 251 is high, otherwise the output of power generator 251 is low.

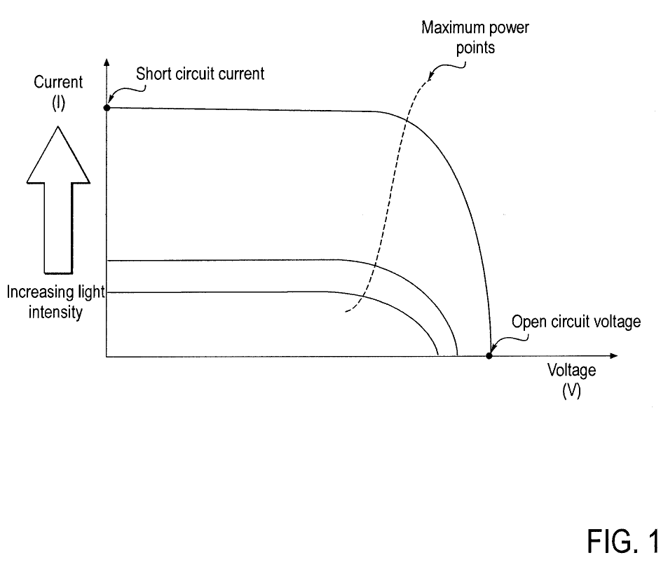

The duty cycle of converter 202 is regulated to produce the maximum value of load current to achieve the maximum power point of operation of solar array 201. As the duty cycle increases, the power output from converter 202 increases, which extracts more power from solar array 201. Because of the current-voltage characteristics of solar cells as shown in FIG. 1, the output voltage of solar array 201 decreases at the expense of higher draw current by converter 202. As the power output from solar array 201 approaches its maximum power point, the current delivered to load 203 increases. As the duty cycle continues to increase beyond the maximum power point, the power extracted from solar array 201 decreases. The decreased power output causes the sensed current signal and the corresponding output voltage 313 to drop. The duty cycle of converter 202 is adjusted to extract more power from solar array 201, and the current draw is increased until the operating point reaches back to the maximum power point. This process repeats to keep the operating point stay within a reasonable bound from the maximum power point, thus the maximum power is always extracted from solar panel 201.

When both inputs to logic comparator 252 that are outputs of power comparator 251 and duty cycle comparator 254, are both high, the output of logic comparator 252 is high and causes amplifier 264 to generate a predetermined voltage output to further charge duty cycle capacitor 261. As such, the duty cycle of converter 202 increases, thus more power is drawn from solar array 201. Table 1 illustrates how the duty cycle is adjusted at logic comparator 252 based on logical inputs from power comparator 251 and duty cycle comparator 254.

TABLE 1
Exclusive NOR logic for duty cycle

| Power Comparator | Duty Cycle Comparator | Duty Cycle |
|---|---|---|
| HIGH | HIGH | Increase |
| HIGH | LOW | Decrease |
| LOW | HIGH | Decrease |
| LOW | LOW | Increase |

As the duty cycle of converter 202 increases, thus more power is extracted, the output voltage from solar array 201 decreases due to the voltage-current characteristics of solar cells as shown in FIG. 1. As the power output from solar array 201 approaches its maximum power point, the current delivered to load 203 approaches its maximum. As the duty cycle is further increased beyond the maximum power point, the power extracted from solar panel 201 decreases, current sensing circuit 303 detects such a change by comparing the output voltage 313 with its previous value. This change in power output beyond its maximum power point changes the output of power comparator 251 to low voltage level, which changes the output of logic comparator 252 low as well. The low output of logic comparator 252 causes the voltage drop by the predetermined voltage at the output of amplifier 264, which causes the voltage built up at duty cycle capacitor 261 to discharge, thus decreasing the duty cycle. The decrease in the duty cycle requires converter 202 to extract a smaller amount of current from solar panel 201, and the operating point again moves towards the direction to the maximum power point.

According to one embodiment, duty cycle comparator 254 detects the change of the duty cycle by sensing the output of voltage follower 263 and changes its output accordingly. The output voltage of voltage follower 263 is used to generate PWM_CTRL signal 269. When both inputs to logic comparator 252 are low, the output of logic comparator 252 becomes high, thus the duty cycle capacitor 261 is charged. The measurements of both duty cycle and power draw at load 203 ensures that maximum power is extracted by solar array 201.

According to one embodiment, over-voltage protection is incorporated to prevent the output voltage of converter 262 from going over a threshold value. This maximum output voltage is set by voltage divider 266. When the sensed voltage 270 of load 203 is greater than the maximum voltage level set by voltage divider 266, over-voltage comparator 265 outputs low voltage, discharges duty cycle capacitor 261 and shuts down converter 202. The output voltage 313 of converter 202 drops until it goes below the set voltage by voltage divider 266. When the output voltage 313 drops below the set voltage, the output of over-voltage comparator 265 changes to high. The duty cycle capacitor 261 is charged through diode 267, and it restarts the MPPT process back to the normal operation.

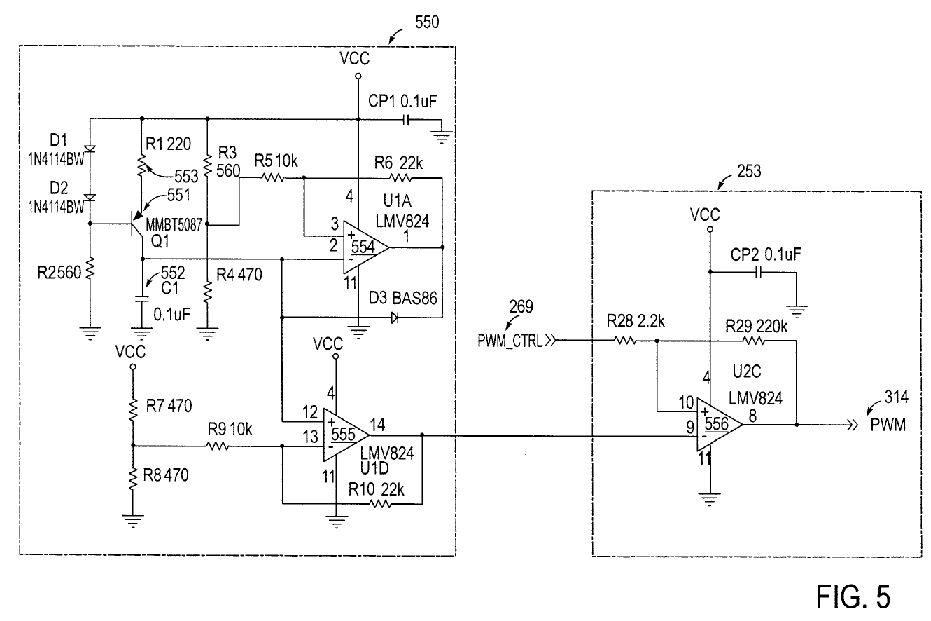

FIG. 5 illustrates an exemplary duty cycle adjust block, according to one embodiment. PWM control block 550 is a saw-tooth signal generator contained in duty cycle adjust block 253. PNP transistor 551 charges capacitor 552 according to the time constant determined by resistor 553 and capacitor 552. Difference amplifier 554 discharges capacitor 552, as such a saw-tooth signal is generated at the output of difference amplifier 555. With the saw-tooth signal at the inverting input and PWM_CTRL signal 269 at the non-inverting input, difference amplifier 556 generates a pulse-width modulated PWM signal 314. The magnitude of PWM signal 314 is determined by PWM_CTRL signal 269. It is noted that PWM control block 550 generating PWM signal may be implemented in many different forms and sizes without deviating the scope of the present invention.

Duty cycle model described herein provides current/voltage tracking with respect to the maximum power point. During a sampling period, duty cycle is increased or decreased using an observed signal so that the operating point is maintained at or near the maximum power point. In a preferred embodiment, the observed signal is output voltage signal 313 whose square is proportional to the output power. For a given configuration (e.g., the number of solar cells in the string or group in the solar panel 201) and operating condition (e.g., the degree of insolation and array temperature), the duty cycle of converter 202 is adjusted to achieve the maximum load current by maximum power tracking control signal 313. If the storage battery 203 is fully charged, constant voltage control signal 814 is used instead to provide a constant output voltage to trickle charge storage battery 203 such that storage battery 203 is maintained at full charge.

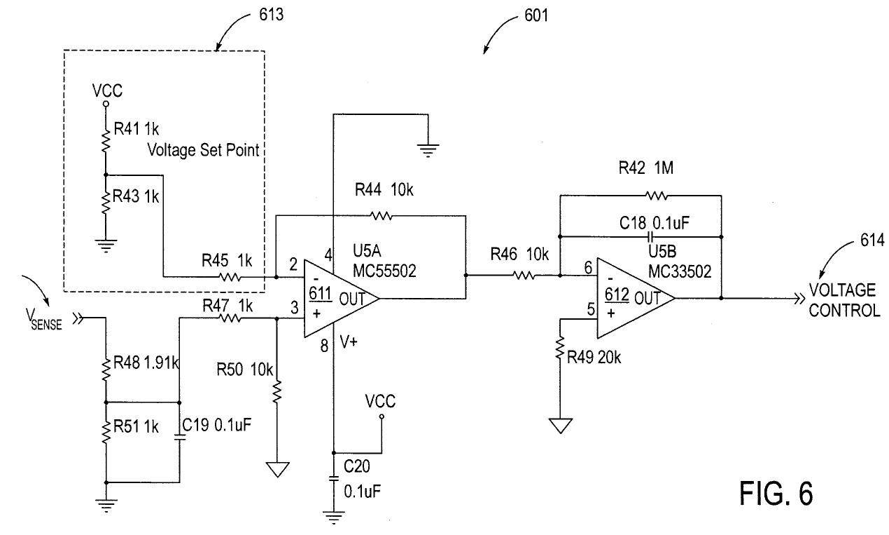

FIG. 6 illustrates an exemplary voltage control block, according to one embodiment. Constant voltage control circuit 601 provides constant output voltage to trickle charge storage battery 203. The non-inverting input of difference amplifier 611 of constant voltage control circuit 601 is the sensed voltage 270 from load 203. The inverting input of difference amplifier 611 is connected to voltage set point divider 613. The output of difference amplifier 611 is connected to integrator 612 to generate voltage control signal 614.

According to one embodiment, voltage control signal 614 is used together with PWM_CTRL signal 269 of MPPT controller 204 to generate PWM signal 314. In this case, constant voltage control circuit 601 replaces the test block 276 of FIG. 4, and switch 275 consisting of forward or reverse biasing of diodes is replaced with a selection circuit, (not shown). The selection circuit selects the greater signal of voltage control signal 614 and PWM signal 314, and provides the output signal to the input signal 269 of duty cycle adjust block 253. The selection circuit may be replaced with switch 275 for manual selection of PWM_CTRL signal 269. Constant voltage control circuit 601 may be used when storage batteries are tied to load 203.

According to one embodiment, the circuit elements used in converter 202 and/or controller 203 are implemented with analog and digital, or mixed-signal components for minimal-delay MPPT control. The use of analog and digital or mixed-signal circuit components in the MPPT system is advantageous over microcontrollers, microprocessors, or digital signal processors for their lower cost and simplicity. Analog/digital circuit components also provide quick responses to the change in operating conditions such as insolation angle and array temperature that effect the operating point of solar array 201.

According to one embodiment, bypass diodes are integrated with a predetermined number of solar cells. The number of solar cells forming a group is determined based on various design factors such as the output voltage of the group, the size of solar cells, other electronics connected thereto. The duty cycle of converter 202 is adjusted to provide maximum load current by maximum power tracking control signal 313. When maximum power tracking control signal 313 fails to produce the maximum load current, constant voltage control signal 614 is used instead, and converter 202 stops charging storage batteries 203. The efficiency of the distributed solar panel is enhanced during shading over the conventional long-string approach (e.g., 18 solar cells in a string) because a smaller number of solar cells are grouped as compared to the long-string approach, and only the solar cells in the group containing a shaded solar cell are affected in the distributed approach.

When a solar cell 211 of solar array 201 is damaged or non-operational for whatever reasons, the string that contains the damaged or non-operational solar cell 211 is excluded from generating power to load 203 by the reverse biasing of diode 322 of converter 202. The rest of solar cells is still operational, even though the output power from solar array 201 might be slightly decreased due to the excluded string.

For a conventional solar array, a number of solar cells are coupled in a string or group. For example, three crystalline solar cells having an open circuit voltage of approximately 0.55 V are grouped to operate at 1.65 V. The number of solar cells grouped in an array (or a group) depends on the bias voltage of each solar cell which varies with the material used to construct the solar cells. According to one embodiment, the number of solar cells in a string is smaller than the typical number of solar cells in a string in conventional solar arrays. Therefore, the power reduction due to a damaged or non-operational solar cell of solar array 201 is minimized as compared to conventional solar arrays.

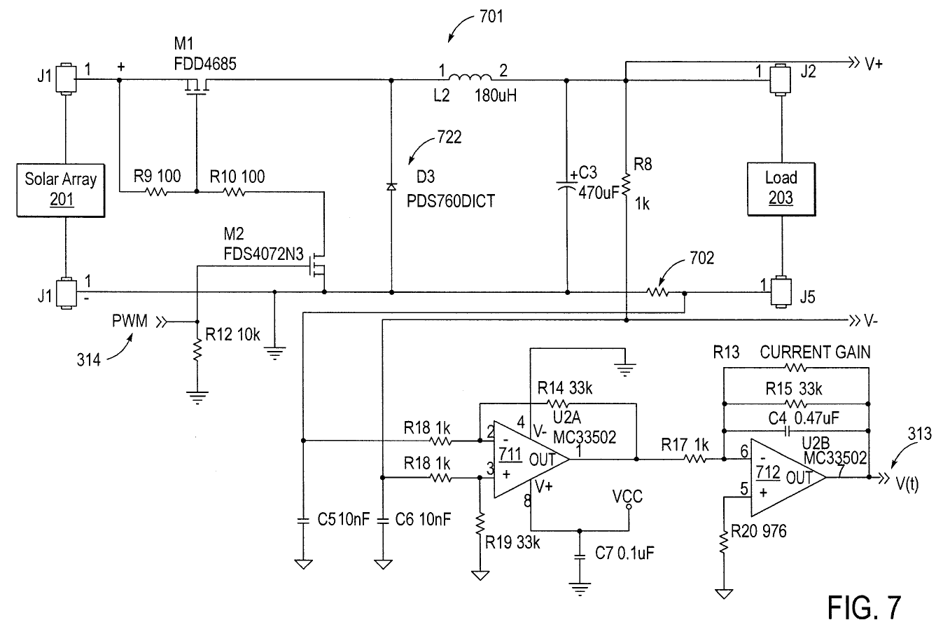

FIG. 7 illustrates an exemplary buck converter, according to one embodiment. Buck converter 701 is a switching converter that steps down the input voltage at the expense of a larger output current. Most commercially available MPPT converters are buck converters. In comparison, converter 301 of FIG. 3 is a boost converter that steps up the input voltage to yield lower output current. Boost converter 301 benefits from using lower gauge conductors, which are relatively cheaper than higher gauge conductors. The reverse biasing of diode 722 of converter 701 isolates non-operational solar cell groups from the distributed system.

According to one embodiment, control loops may be added to perform additional functions. For example, a constant-current control loop or a constant-voltage control loop may be incorporated to draw constant current or constant voltage from solar array 201. Any or all of the these control loops may be incorporated into controller 204 and called upon to function and control the converter as determined by operating conditions.

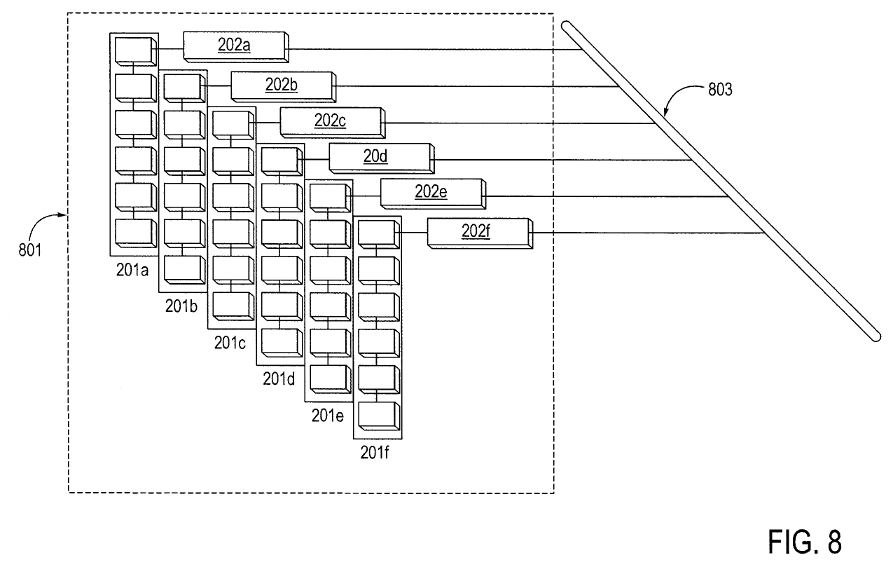

FIG. 8 illustrates an exemplary solar array with distributed converters, according to one embodiment. In the present example, six solar cells are grouped to form a solar cell group 201, and solar array 801 contains six solar cell groups, but it is appreciated that any number of solar cells and any number of solar cell groups may be grouped to form solar array 801. Distributed MPPT converters 202a-202f may be implemented into either integrated circuits or discrete circuits. Each MPPT converter 202 provides dedicated control and power conversion for each solar cell group 201. Distributed MPPT converter 202 integrates MPPT controller 204 therein and may be placed within or outside of solar array 201. The number of solar cells grouped in solar cell group 201 and tied to distributed MPPT converter unit 202 may depend on the solar cell material as well as the configuration. According to one embodiment, the CuGaSe2 solar cell is connected in series with Cu(In, Ga)Se2 solar cell to produce a stacked tandem solar with an open circuit voltage of 1.18V. Solar array 201 charges storage battery 203 (not shown) on common charge bus 803.

When the output voltage from a solar cell group falls below a threshold voltage to operate the associated distributed MPPT converter, the solar cell group is isolated from other solar cell groups that produce sufficient output voltage. For example, the output voltage of solar cell group 201c may fall below the threshold voltage to generate any power by the shading effect or damaged solar cells contained therein. Because shaded or damaged solar cells present large impedance to the associated solar cell group, often drawing power rather than generating power, solar cell group 201c containing the shaded or damaged solar cells is automatically disabled by the reverse-biasing diode of distributed converter 202c. The rest of the distributed MPPT converters 202a, 202b, 202d, 202e, and 202f are still generating power to common charge bus 803.

According to one embodiment, multiple solar cell groups 201 are grouped to form solar array 801 to provide higher output power. Each solar cell group 201 having a dedicated distributed MPPT controller 202 may be connected directly to charge bus 802 without having a conventional maximum power point tracking converter for the entire solar array. Although FIG. 8 illustrates parallel configuration of distributed MPPT converters 202 when coupled to charge bus 803, serial or mixed (combination of parallel or serial) configuration of distributed MPPT converters may be used.

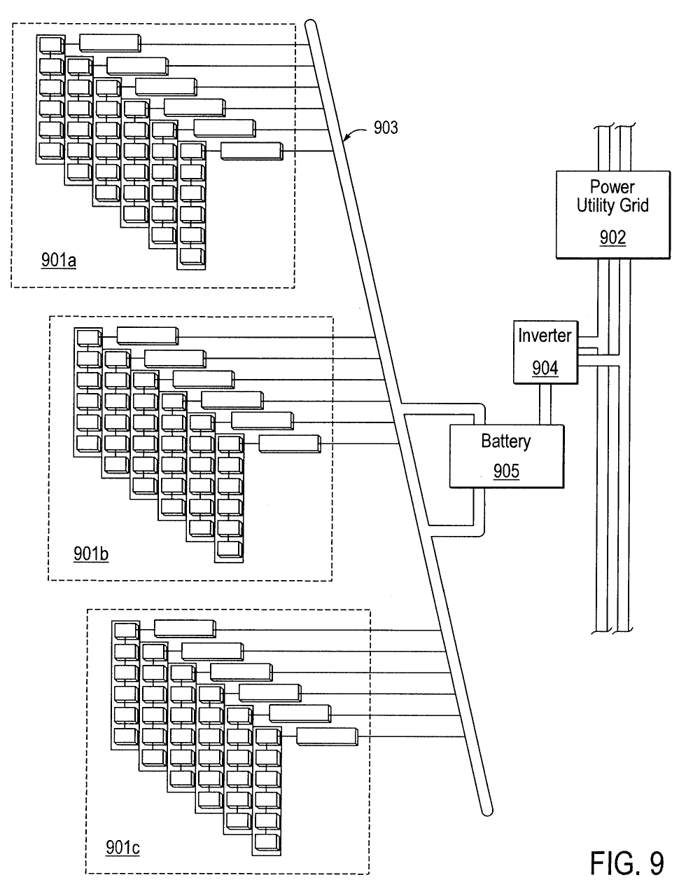

FIG. 9 illustrates an exemplary solar panel connected to a power utility grid, according to one embodiment. One or more solar panels 901 are connected to storage battery 905 via charge bus 903. Storage battery 905 is connected to inverter 904 that transfers electric power generated by solar panels 901a-901c to power utility grid 902. Battery 905 may be omitted for a non-storage back-up inverter system tied to power utility grid 902.

A method and system for providing a maximum power point tracking converter for use with one or more solar cells in a string or group in a distributed manner within a solar photovoltaic array is disclosed. Although various embodiments have been described with respect to specific examples and subsystems, it will be apparent to those of ordinary skill in the art that the concepts disclosed herein are not limited to these specific examples or subsystems but extends to other embodiments as well. Included within the scope of these concepts are all of these other embodiments as specified in the claims that follow.

We claim:

1. A system comprising:
a solar panel comprising a plurality of solar cells, wherein one or more solar cells are grouped to form a plurality of solar cell groups;
a converter adapted to draw power from each solar cell group; and
a distributed control unit adapted to provide maximum power point tracking for each solar cell group.

2. The system of claim 1, wherein the distributed control unit is integrated into the converter.

3. The system of claim 1, wherein the converter is one of a step-up converter, a step-down converter, a step-up/step-down converter, and a push-pull converter.

4. The system of claim 1, wherein the solar panel is connected to a power bus.

5. The system of claim 4, wherein the power bus is connected to a power grid through an inverter.

6. The system of claim 4, wherein the converters for the plurality of solar cell groups are connected in parallel before coupled to the power bus.

7. The system of claim 4, wherein the converters for the plurality of solar cell groups are connected in series before coupled to the power bus.

8. The system of claim 4, wherein the converter that is connected to a shaded or non-operational solar cell group is isolated from the power bus by a reverse biasing diode.

9. The system of claim 1, wherein the distributed control unit comprises:
a power sensing block adapted to measure a power signal associated with the power drawn from each solar cell group;
a duty cycle adjust block adapted to measure and adjust duty cycle for each solar cell group;
a power comparator adapted to generate a first logical signal by comparing the power signal with previously measured power signal for each solar cell group;
a duty cycle comparator adapted to generate a second logical signal by comparing the duty cycle with previously measured duty cycle; and
a logic comparator adapted to provide a control signal for the duty cycle adjust block using the first logical signal from the power comparator and the second logical signal from the duty cycle comparator.

10. The system of claim 9, wherein the distributed control unit does not require a microprocessor for operation.

11. The system of claim 9, wherein the power sensing block measures the power signal by sensing current drawn by a load connected to the converter.

12. The system of claim 9, wherein the power sensing block measures the power signal by sensing voltage measured at a load connected to the converter.

13. The system of claim 9, wherein the power comparator compares the present power signal with the rolling average of the previously measured power signals.

14. The system of claim 9, wherein the previously measured power signal is stored in a resistive-capacitor circuit.

15. The system of claim 9, wherein the distributed control unit further comprises a voltage controller adapted to trickle charge a storage battery once the storage battery is fully charged, the storage battery stores electrical energy drawn from the solar panel.

16. The system of claim 9, wherein the distributed control unit further comprising
an over-voltage protection circuit adapted to limit the upper bound of the duty cycle.

17. The system of claim 9 further comprising an exclusive NOR gate, wherein the exclusive NOR gate receives the first logical signal and the second logical signal as inputs signals.

18. The system of claim 9, wherein the duty cycle for each solar cell group is adjusted with a PWM signal generated by the control signal.

19. A method for extracting maximum power from a solar panel, the method comprising:
grouping one or more solar cells of the solar panel to form a plurality of solar cell groups;
independently measuring a power signal that is associated with power drawn from each solar cell group;
extracting power from each solar cell group using a converter; and
maintaining the power drawn from the converter for each solar cell group at its maximum capacity using a distributed control unit such that maximum power is extracted from each solar cell group.

20. The method of claim 19, wherein the distributed control unit is integrated into the converter.

21. The method of claim 19, wherein the converter is one of a step-up converter, a step-down converter, a step-up/step-down converter, and a push-pull converter.

22. The method of claim 19, wherein the solar panel is connected to a power bus.

23. The method of claim 22, wherein the power bus is connected to a power grid through an inverter.

24. The method of claim 22, wherein the converters for the plurality of solar cell groups are connected in parallel before coupled to the power bus.

25. The method of claim 22, wherein the converters for the plurality of solar cell groups are connected in series before coupled to the power bus.

26. The method of claim 22, wherein the converter that is connected to a shaded or non-operational solar cell group is isolated from the power bus by a reverse biasing diode.

27. The method of claim 16 further comprising:
continuously measuring the power signal and duty cycle for each solar cell group;
comparing the power signal with previously measured power signal using a power comparator;
generating a first logical signal as a result of the power signal comparison;
comparing the duty cycle with previously measured duty cycle using a duty cycle comparator;
generating a second logical signal as a result of the duty cycle comparison;
generating a control signal using the first logical signal and the second logical signal; and
adjusting the duty cycle of each solar cell group using the control signal.

28. The method of claim 27, wherein the distributed control unit does not require a microprocessor for operation.

29. The method of claim 27 further comprising measuring the power signal using a current sensing block.

30. The method of claim 27 further comprising measuring the power signal using a voltage sensing block.

31. The method of claim 27, wherein the power comparator compares the power signal with the rolling average of previously measured power signals.

32. The method of claim 27 further comprising trickle charging a storage battery once the storage battery is fully charged, wherein the storage battery stores electrical energy drawn from the solar panel.

33. The method of claim 27 further comprising providing over-voltage protection by limiting the upper bound of the duty cycle.

34. The method of claim 27, wherein the control signal is generated by an exclusive NOR gate, wherein the exclusive NOR gate receives the first logical signal and the second logical signal as inputs signals.

35. The method of claim 27, wherein the duty cycle for each solar cell group is adjusted with a PWM signal generated by the control signal.
